(19) United States
(12) Patent Application Publication
(10) Pub. No.: US 2006/0062899 A1
(43) Pub. Date: Mar. 23, 2006

(54) Method of discontinuous stripe coating

(75) Inventors: Charles M. Rankin JR., Penfield, NY (US); William D. Devine, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/944,516

(22) Filed: Sep. 17, 2004

(51) Int. Cl. B05D 5/12; B05D 5/06; B05D 1/30

(52) U.S. Cl. 427/58; 427/66; 427/420

(57) ABSTRACT

A die-coating method of forming parallel, spaced-apart stripes is advantageous for the manufacture of various materials. Each of the stripes has at least two layers comprising at least two different materials.

### CROSS REFERENCE TO RELATED APPLICATIONS

Reference is made to commonly assigned, co-pending U.S. patent application Ser. No. ______ by Charles M. Rankin et al. (Docket 88360) filed of even date herewith and titled “APPARATUS FOR FORMING DISCONTINUOUS STRIPE COATINGS” and U.S. patent application Ser. No. ______ by Charles M. Rankin et al. (Docket 87091) filed of even date herewith and titled “METHOD OF MAKING A DISPLAY SHEET COMPRISING DISCONTINUOUS STRIPE COATING.”

### FIELD OF THE INVENTION

The present invention relates to the coating of materials in the form of parallel, spaced apart stripes.

### BACKGROUND OF THE INVENTION

The die-coating technique, typically involving the use of a die set (also referred to herein as a die assembly), has been in commercial use since the nineteen fifties. (Die-coating is used herein to encompass slot coating and extrusion coating, all of which involve the use of a die assembly to form a coating.) This technique was first applied to form a continuous coating of a large area. Presently, this technique is also used to form various functional coatings in the electronic and information industries. For example, a die-coating technique is used to form a stripe coating in which multiple stripes are formed on a substrate. Such stripe coating may involve special die design and precision coating techniques. A stripe-coating technique not only can be utilized to produce a conventional product such as an adhesive tape but also can be employed to fabricate advanced electronic devices such as laser printers and Li batteries.

U.S. Pat. No. 4,469,782 to Ishiwata et al. discloses a method for simultaneously coating a plurality of different coating liquids in a side-by-side fashion (adjacent stripes of varying widths), within the opening slot of an extrusion device by the use of laterally spaced separators. A series of three slot openings (from which extrusion coatings are applied to a moving substrate) are vertically stacked to accomplish simultaneous three-layer coatings, each layer of which may include the aforesaid adjacent stripes. The side-by-side, liquid-to-liquid contact between stripes can be effected prior to, or at, their extrusion from the slot opening. This patent pertains to coatings for photographic film units of the diffusive transfer-process type. The purpose of the stripes is so that relatively expensive image-processing materials are only coated in the image area (whereas lateral “dummy” materials are coated laterally in non-image areas), thus resulting in economical use of expensive processing materials.

U.S. Pat. No. 6,159,544 to Liu et al. discloses a method for forming coating layers of alternating stripes in an ABABAB etc. pattern. This patent discloses a die set and method for the production of such multiple stripes of different materials adjacent to each other but does not disclose coating of layers on top of one another. The die set comprises, assembled in sequence, an upper die, an upper shim, guide shim, lower shim, and lower die. The guide shim, in particular, comprises a plurality of spaced first-flow distribution blocks projecting from the upper side, and a plurality of distribution passages connected the lower side of the guide shim and the upper side, and an outlet of each distribution passage being located between two legs of each first-flow distribution block. Accordingly, when fed into the die-coater, liquid A will pass around the plurality of first distribution blocks and liquid B will enter the distribution passages and exit from the outlets thereof, so that liquids A and B will join at positions near the two legs of each of the first distribution block, thereby forming an ABAB pattern.

U.S. Pat. No. 6,423,140 to Liu et al. disclose the formation of three different and repeated stripes ABAABC or A_B_C, where the symbol “_” implies that there is no coating between two adjacent stripes. Accordingly, three different coating solutions flow into a die assembly through different inlet positions. The die set comprises a guide shim and a guide die inserted between two coating dies.

U.S. Pat. No. 4,106,437 to Bartlett discloses an apparatus for multiple stripe coating of a web with a liquid coating composition, which apparatus is comprised, of a hopper having a pair of spaced lips and a pair of shims mounted in face-to-face arrangement within the hopper and positioned between the spaced lips and between (instead of an upper and lower die) a cover plate and a trough. One of the shims is provided with a plurality of open-ended channels while the second shim is equipped with a plurality of projecting portions, corresponding in width and location to the desired stripes, which are in alignment with the open-ended channels and project beyond the open ends thereof. The apparatus is stated to be capable of carrying out multiple-stripe coating of a web at high speeds and with a high degree of precision in regard to stripe width and registration. The stripes are spaced apart, not adjacent. Bartlett states that vacuum is advantageously utilized to stabilize the coating operation at high speed as is well known in the coating art. Bartlett states that stripe width and registration can be reproduced with accuracy within a few thousandths of an inch. Bartlett mentions that a variety of coatings can be made, for example, a dye-containing polymeric dispersion, a magnetic dispersion, phosphor dispersion, or adhesive dispersion. Bartlett, however, does not explain the function of having a plurality of spaced-apart stripes on a web material or an advantage of such an arrangement of stripes.

U.S. Pat. No. 4,324,816 to Landis et al. discloses a method of extrusion coating a magnetic dispersion on a web in the form of a narrow stripe. The magnetic dispersion exhibits a decrease in viscosity as the shear rate is increased. The stripe has predetermined uniform cross-sectional dimensions including substantially uniform thickness, and is coated onto a moving web by means of a die maintained in a predetermined spaced relation with the web. The die has two or more bores through which the extrudable material is extruded in columns onto the moving web to form the stripe thereon. For example, a six-bore die could be used to coat a 100-mil magnetic stripe on 16 mm film.

Japanese patent publication No. 8-038972 A discloses methods for producing multiple-stripe coatings, in which a stripe pattern consisting of plural colors is continuously coated on a belt-like material. Also, easily changing the width of a stripe is made possible. A manifold is provided in the inside of a metallic material apart from a slot part for discharging a coating material. A plurality of through-holes that communicate with the slot part, and a plurality of coating-liquid feed-ports that communicate with a coating-liquid feed device outside of a die main body, are formed in the manifold.

U.S. Pat. No. 5,700,325 to Watanabe discloses methods for forming a coating film in a spaced-apart stripe pattern. In this patent, the coating device is a nozzle comprising a front block that is positioned in the up-stream side, in a base-material (moving web) running direction, and a back block is positioned in the down-stream side. The front block is projected more than the back block toward the base material, and jetting-out holes for a coating material are formed in the flat face of the back block. When the base material (web) is moved along the surface of the nozzle composed in this way, the base material moves along the curved face of the front block and continuously moves above the back block of the nozzle in which jetting-out holes for a coating material are formed. Consequently, a coating film in a stripe pattern with no fluctuation of width is formed on the surface of the base material. In one embodiment (FIGS. 13-15 of U.S. Pat. No. 5,700,325), the coating device enables the application of different kinds of coating materials on a surface of a base material in a multi-layered structure, for example, a continuous layer is simultaneous coated over or under a layer of stripes. A series of stripes ABC can also be formed in a single layer, each stripe being of a different material.

When a coating product of multiple spaced-apart stripes is made, there is a tendency that the borders or edges of the stripes lose their sharp edges, which may extend outward and become thinner, and thus a coating layer of inferior uniformity and low interfacial quality is formed. Thus, it is difficult to ensure a definite and precise border for the “stripes,” adjacent each uncoated longitudinal inter-stripe space or “gap.” Perhaps for that reason, the aforesaid prior art references do not disclose a technique for forming a coating layer of multiple spaced-apart stripes composed of two or more materials A, B and C on top of one another.

### SUMMARY OF THE INVENTION

The present invention provides a method of coating comprising forming an extended coating layer comprising a plurality of spaced-apart parallel stripes, each stripe composed of at least two different materials in an arrangement of vertically stacked stripes on top of one another comprising in a repeated pattern, stripes alternating with at least one uncoated lateral longitudinal space in the extended coating layer.

In one embodiment of the invention, the stripes form a pattern comprising at least two stripes as follows:

$$\frac{B}{A} ** \frac{B}{A}$$

For example, in the case of three stripes, the striped pattern can be represented as follows:

$$\frac{B}{A} ** \frac{B}{A} ** \frac{B}{A}$$

The symbol “**” implies that there is no coating between two adjacent parallel stripes. A and B represent at least two different coating liquids, and B has an distinct interface with A in each stripe. The width of the lateral longitudinal space between the stripes is relatively narrow compared to the width of the stripes, and the stripes are formed under suction.

In a second embodiment of the present invention, the method of coating comprises forming an extended coating layer comprising a plurality of spaced-apart parallel stripes, each stripe composed of at least two different materials in an arrangement of vertically stacked stripes on top of one another comprising in a repeated pattern, stripes alternating with at least one uncoated lateral longitudinal space in the extended coating layer, wherein at least two stripes are formed as follows:

$$\begin{matrix}\underline{C} \underline{C} \\ {{\underline{B}}^{*}}^{*} \underline{B} \\ A A\end{matrix}$$

For example, in the case of three stripes, the striped pattern can be represented as follows:

$$\begin{matrix}\underline{C} \underline{C} \underline{C} \\ \underline{B} ** \underline{B} ** \underline{B} \\ A A A\end{matrix}$$

Again, the symbol “**” implies that there is no coating between two adjacent parallel stripes. A, B, and C represent at least two different coating liquids, and B has an distinct interface with A and C. The width of the lateral longitudinal space between the stripes is relatively narrow compared to the width of the stripes, and the stripes are formed under suction.

The coating liquids A, B and C can correspond to three different materials or, alternatively, any two of the coating liquids can be the same material, for example, A and C or B the same material.

The width of each of the stripes and spaces can independently be the same or vary within the same pattern. In one preferred embodiment, the composition being coated comprises an electro-optical material. In another embodiment, the composition being coated comprises a light-emitting material. Various other materials can be coated for diverse applications.

### BRIEF DESCRIPTION OF THE DRAWINGS

FIG. 1 is a partially sectional view of a die set according to one of the preferred embodiments of the present invention;

FIG. 2 is a striped sheet made according to the present invention;

FIG. 3 is a cross-section of the sheet of FIG. 2;

FIG. 4 is a partially sectional view of the lower die element and associated guide shim of the die set shown in FIG. 1;

FIG. 5 is a top view of the middle die element and associated guide shim of the die set shown in FIG. 1;

FIG. 6 is a side cross-sectional view of the die set of FIG. 1 showing the formation of the coated layer;

FIG. 7 is a schematic, partially sectional view of another embodiment of a coating apparatus used to produce flexible sheets, for coating three stacked layers in stripes;

FIG. 8 is a side view of an OLED display element that can be manufactured using the apparatus according to the present method;

FIG. 9 is a partial cross-sectional perspective of one embodiment of a display that can be manufactured using the apparatus in accordance with the present invention, in which a polymer-dispersed liquid crystal-material is coated;

FIG. 10 is top view of a continuous common substrate having a plurality of display elements formed in association with a three-stripe coating made using the apparatus in accordance with the present invention;

FIG. 11 is a top view of another embodiment of the invention showing a continuous common substrate having a plurality of display elements formed in association with a two-stripe coating made using the apparatus in accordance with the present invention, wherein each of the exposed longitudinal areas, between striped layers of cholesteric material, form unexposed conductors for both of the adjacent rows of display elements in adjacent stripes;

FIG. 12 is a magnified extended top view of a display element shown diagrammatically in FIG. 3 but showing the greater number of first electrodes commonly used during the manufacture of a pixilated display;

FIG. 13 is a side view of the display element taken through section 13-13 of FIG. 12 showing a substrate as a portion of common substrate having selectively stripe coated material over first conductors and isolation pads;

FIG. 14 is a top view of one embodiment of the display element of FIG. 12 with printed second conductors;

FIG. 15 is a bounded side view of the display element of FIG. 14 with printed second conductors having electrically addressable pixels, which side view is taken through section 15-15 of FIG. 14;

FIG. 16 is an extended front view of the display element of FIG. 15 electrically addressable pixels that can be made using the present invention; and

FIG. 17 is a top plan view of a display sheet comprising segmented display elements that can be made in accordance with the present invention having electrical contacts between stripes.

### DETAILED DESCRIPTION OF THE INVENTION

A die-coating process is disclosed for coating of various materials including, for example, imaging or sensing materials such as liquid-crystal materials or other electro-optical materials. In the present method, a coated sheet can be formed using inexpensive, efficient layering methods. In a preferred embodiment of this invention, the flexible web is only coated where needed by the use of a die set that restricts the flow of coating material to form stripes.

To illustrate one application, displays in the form of sheets in accordance with the present invention are inexpensive, simple, and fabricated using low-cost processes. For example, a large volume of sheet material can be coated on a moving flexible web and later formed into smaller sheets corresponding to individual display components or elements for use in display devices such as transaction cards, signage, labels, and the like. The stripes form longitudinal rows of a series of potential individual displays as will be described in greater detail below.

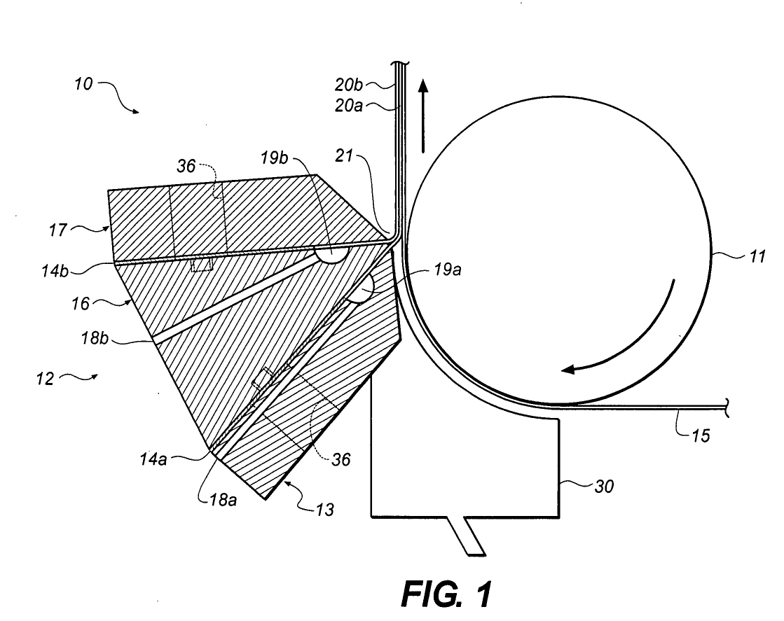

FIG. 1 is a schematic, partially sectional view of one embodiment of a slot-coating apparatus 10 that can be used to produce striped coatings according to the invention. Flexible web 15 is conveyed in the direction of the arrow through a coating zone by a conveyance means that includes a backing roller 11, which precisely positions the flexible web 15 in relation to the die assembly 12. The die assembly 12 includes lower die element 13, bottom-layer shim 14a, center die element 16, second-layer shim 14b, and upper die element 17. The die assembly 12 can distribute a plurality of coating liquids of the desired stripe width by means of feed conduits 18a, 18b and cavities 19a, 19b. Coating liquids are supplied to the feed conduits 18a, 18b at the desired flow rate by appropriate fluid delivery means (not shown). Through openings 36 (for example, slots or holes) are provided on opposite sides of die elements 13 and 17, extending through shims 114a, 114b, respectively, leading to threaded cylinders for attachment by means such as a threaded bolt (not shown) in order to fasten the die elements and shims together, as well known in the art. Additional positioning means well known in the art such as dowels and dowel holes (not shown), can be used to further position the shims and die elements.

The moving flexible web 15 receives the superimposed (stacked) coated striped layers 20a and 20b formed by the die assembly 12 on its surface at coating bead 21. The superimposed coated striped layers 20a and 20b move to subsequent operations such as chill setting and drying (not shown). It is also possible to have additional layers (continuous coatings, striped coatings, or otherwise selectively coated layers) coated in a downstream operation either before or after the coated striped layers 20a and 20b are completely dried.

The die-coating apparatus 10 (also referred to as a slot-coating apparatus) preferably includes a low-pressure or vacuum chamber (suction chamber) 30 that is used to stabilize the coating bead 21 by imposing a pressure difference across the coating beads for obtaining uniform coating laydown for each stacked stripe of material. Such a suction chamber is disclosed, for example, in U.S. Pat. No. 2,681,294 to Beguin, incorporated herein by reference.

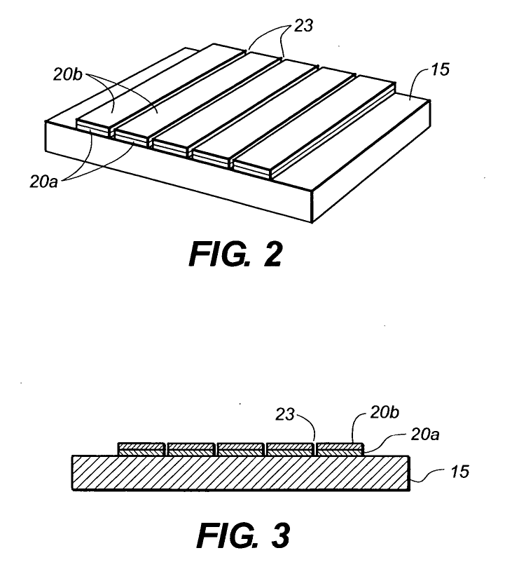

An object of the present invention is to apply a plurality of superimposed layers of coating composition to a substrate in a plurality of transversely discontinuous (spaced apart) parallel superimposed stripes 20a, 20b as shown in FIG. 2 and, in cross-section, FIG. 3. In accordance with the present invention, the spaced distance of longitudinal spaces 23 between individual stripes can be as low as 0.75 mm (0.030 inch) and as high as 50 mm (2 inches) when the coating beads are stabilized by the suction chamber. Preferably, the spacer width between stripes is 1.5 mm to 12.0 mm (about 0.0.04 to 0.48 inch), more preferably about 2.0 mm to 6.0 mm. The width of one or more of the stripes can depend on the size of the display elements and can be, for example, 100 mm (4 inches), 500 mm (20 inches), 1500 mm (about 60 inches) or higher, depending on whether the display is used for a label, outdoor signage, or other application. The width of the stripes and spaces can independently vary if desired.

In accordance with one embodiment of the present invention, the stripes of coating composition are formed in the die assembly by means of shims that are placed between die-element surfaces that are in a parallel, face-to-face relationship, in which one of the element surfaces contains a fluid distribution cavity. In the preferred embodiment, the shim is a thin relatively flat piece that is wedged between the die elements to control the flow of materials through the die assembly and out the slots of the die assembly.

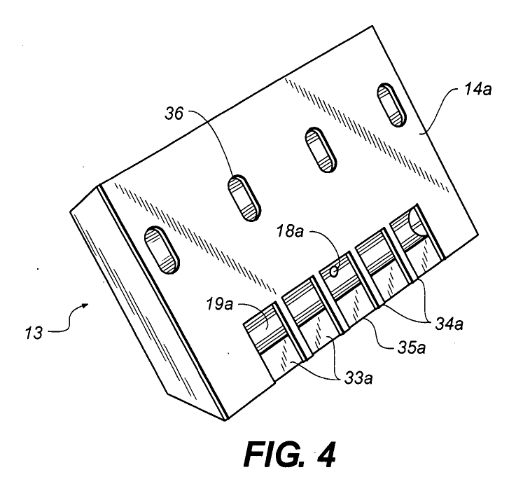

FIG. 4 shows the lower die element 13 and bottom layer shim 14a of the die-coating apparatus or device 10 of FIG. 1. In this embodiment, the shim, which can be metallic or plastic or other solid material, is used to distribute the bottom coating composition (herein referred to as coating fluid A) for a plurality of coated striped layers such as coated stripe layer 20a into a plurality of longitudinally parallel transversely discontinuous stripes. Coating fluid A enters the die assembly through conduit 18a which communicates with cavity 19a which distributes the coating fluid A in stripes in a direction perpendicular to the edge of the flexible web to be coated. Bottom-layer shim 14a contains channels 33a. Coating fluid A flows from cavity 19a to the lower lip 35 through the channels 33a. However, flow is prevented from occurring in the areas covered by the projecting portions or distribution blocks 34a of the bottom-layer shim 14a. Thus, spaced-apart stripes of the bottom layer coating fluid A are formed through this arrangement of distribution passages 33a and distribution blocks 34a of the bottom-layer shim 14a. The precise width of the stripes of bottom layer coating composition can be controlled by the arrangement of channels 33a and distribution blocks 34a of bottom-layer shim 14a. Similarly, the position of the stripes of bottom layer coating fluid A relative to the edges of the flexible web 15 can be controlled by the position of the die assembly relative to the edges of the substrate 15. Through openings 36 (for example, slots or holes) in shims 14a, 14b and die elements 13, 16, and 17 of FIG. 1 are seen to allow means for fastening the die elements and shims together as explained above.

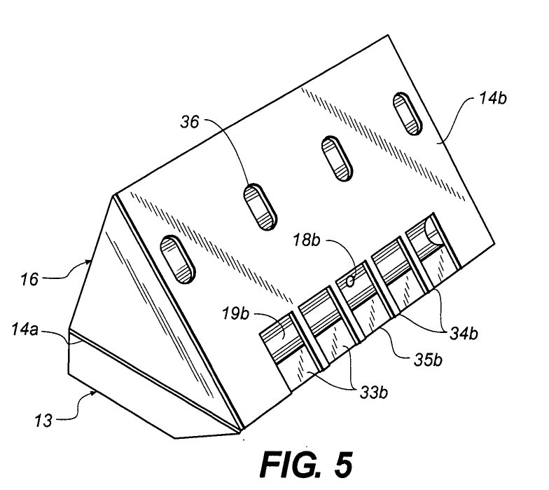

FIG. 5 is a view of the center die element 16 and second-layer shim 14b in the slot-coating apparatus of FIG. 1. Second-layer shim 14b is placed between the top face of center die element 16 and the lower face of upper die element 17 (shown in FIG. 1 but not FIG. 5). A secondary coating fluid B enters the center die element 16 through conduit 18b which communicates with cavity 19b and which distributes the coating liquid in stripes in a direction perpendicular to the edge of the flexible web to be coated. Upper-layer shim 14b contains distribution passages 33b and distribution blocks 34b. Coating fluid B flows from cavity 19b to the upper lip 35c through distribution passages 33b. However, flow is prevented from occurring in the areas covered by the distribution blocks 34b of the shim 14b. Thus, stripes of upper-layer coating fluid B are formed through this arrangement of channels 33b and distribution blocks 34b of the upper-layer shim 14b. This secondary layer of coating composition is superimposed, in register, on the bottom layer at the upper lip 35c by aligning distribution passages 33b and distribution blocks 34b of upper shim 14b with the distribution passages 33a and distribution blocks 34a of bottom layer shim 14a associated with the lower die element 13.

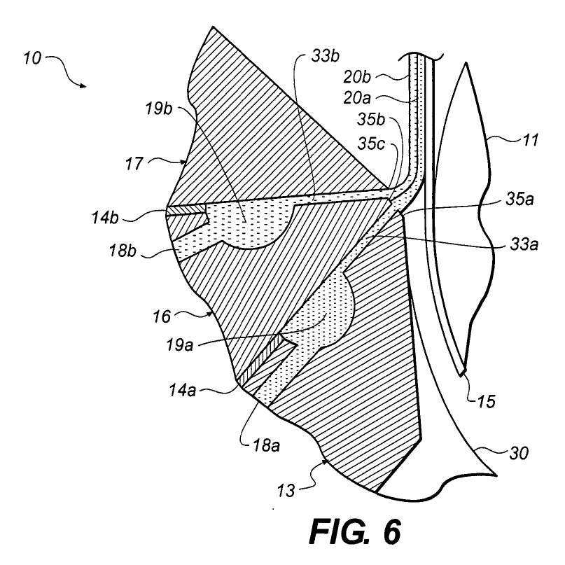

FIG. 6 provides a view of the formation of the coating bead when using the die set of FIG. 1. Coating fluid A flows from cavity 19a to the lower and middle lips 35a, 35b, respectively, through the distribution passages 33a, and coating fluid B flows from cavity 19b to the middle and upper lips 35b, 35c, respectively, through distribution passages 33b. It then makes contact with the flexible web 15, which is against the backing roll 16.

The skilled artisan will appreciate that conventional coatings dies can be used instead of the die assembly of FIG. 1, depending on the application or the coating pattern and number of layers. Also, alternate embodiments of the die assembly of FIG. 1 can involve, for example, replacing one or more of the guide shims by machining/grinding the shim shape directly into the die elements themselves. However, this is a less versatile approach, since shims can be easily substituted between die elements for coating different patterns, shapes and various size stripe widths and spaces, etc.

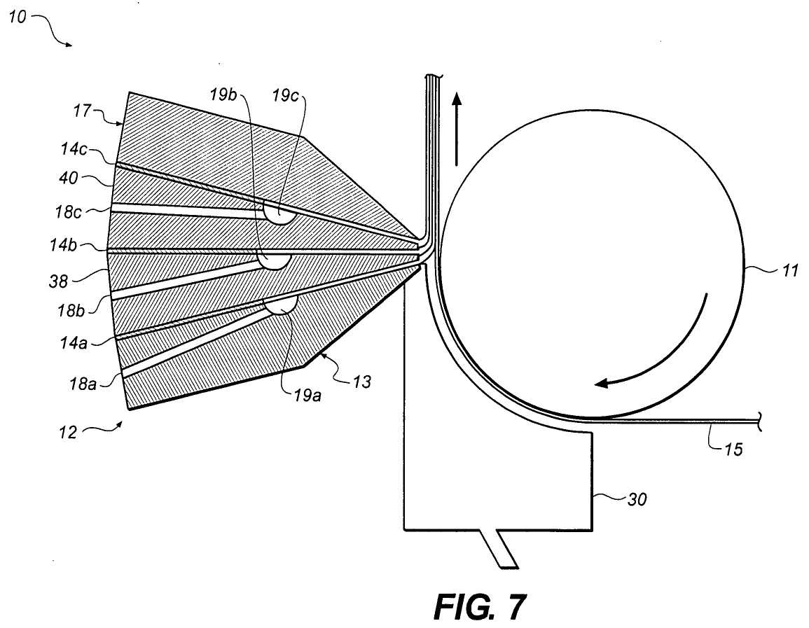

Also, a similar die assembly can be made that coats three-stacked stripes by having two center die elements, as will be understood by the skilled artisan, wherein an additional center die element which can be positioned between the lower die element 13 and center die element 16 shown in previous figures. Such an embodiment is seen in FIG. 7 showing a schematic, partially sectional view of a one embodiment of a slot-coating apparatus 10 used to produce flexible sheets according to the invention. Flexible web 15 is conveyed in the direction of the arrow through a coating zone by a conveyance means that includes a backing roller 11, which precisely positions the flexible web 15 in relation to the die assembly 12. The die assembly 12 includes lower die element 13, bottom-layer shim 14a, a first center die element 38, second-layer shim 14b, second center die element 40, a third-layer shim 14c, and upper die element 17. The die assembly 12 can distribute a plurality of coating liquids of the desired stripe width by means of feed conduits 18a, 18b, 18c and cavities 19a, 19b, 19c. Coating liquids are supplied to the feed conduits 18a, 18b, 18c at the desired flow rate by appropriate fluid delivery mean's (not shown). The moving flexible web 15 receives the superimposed (stacked) coated striped layers formed by the die assembly 12 on its surface. A low-pressure or vacuum chamber (suction chamber) 30 is used to stabilize the coating beads formed at the slot opening by imposing a pressure difference across the coating beads, thereby promoting uniform coating laydown for each stacked stripe of material.

The die set used in this example can be made by utilizing the conventional mold making art. However, a precision fabrication technique will be required to control the tolerance within a few micrometers, when the width of the coating stripes is reduced to a level of 20-150 micrometers.

The present invention is directed to a method of coating comprising forming an extended coating layer comprising a plurality of spaced-apart parallel stripes, each stripe composed of at least two different materials in an arrangement of vertically stacked stripes on top of one another comprising in a repeated pattern, stripes alternating with uncoated spaces or indentation in the extended coating layer, as follows:

$$\frac{B}{A} ** \frac{B}{A} ** \frac{B}{A}$$

wherein the symbol “**” implies that there is no coating between two adjacent stripes. A and B represent at least two different coating liquids, and B has an distinct interface with A in each stripe. The width of the lateral space between the stripes is relatively narrow compared to the width of the stripes, and the stripes are formed under suction.

Another embodiment of the present method comprises forming an extended coating layer comprising a plurality of spaced-apart parallel stripes, each stripe composed of at least two different materials in an arrangement of vertically stacked stripes on top of one another comprising in a repeated pattern, stripes alternating with uncoated spaces or indentation in the extended coating layer, as follows:

$$\begin{matrix}\underline{C} \underline{C} \underline{C} \\ \underline{B} ** \underline{B} ** \underline{B} \\ A A A\end{matrix}$$

wherein the symbol “**” implies that there is no coating between two adjacent stripes. A, B, and C represent at least two different coating liquids, and B has an distinct interface with A and C. The width of the lateral space between the stripes is relatively narrow compared to the width of the stripes and wherein the stripes are formed under suction. The above patterns are representative two or more stripes even though three stripes are shown to illustrate the pattern. In one embodiment of the invention, liquids A, B and C correspond to three different materials. In another embodiment, two of A, B and C are the same material. In one embodiment, at least one of A and B comprise an electro-optical fluid having a plurality of optical states responsive to electric fields. For example, the electro-optical fluid can comprise a liquid crystal or an electrophoretic material. Another application involves the making of sensors in which at least one of A and B comprise a material for a sensor that, upon detecting a stimuli, allows an electrical signal to be detected by first and second conductors. For example, the material for a sensor can comprise an organic light emitting diode material.

In the case where displays are being manufactured, at least one of A and B can comprise an electro-optical material and the other can comprise a darkly pigmented material, for example, a nanopigment.

In one embodiment of the method of the present invention, further steps can comprise coating a second field-carrying layer over the extended stripe-coated layer, thereby forming second conductors. The method can further comprise depositing a plurality of tracers that connect the second conductors to contact points located in the space between stripes, optionally with a dielectric layer coated between the second conductors and the tracers.

Since the stripes can form longitudinal rows of a series of potential individual elements, subsequent manufacturing operations can include cutting the stripes perpendicular to their longitudinal direction to form individual elements; and cutting the coated web in the longitudinal direction to form stripes each containing a single stripe and at least a portion of at least one space between stripes. If the flexible web is only coated where needed by the use of a die set that restricts the flow of the material used to form stripes, then the selective removal of material from the extended layer, such as by skiving, can be partially or completely avoided.

In one preferred embodiment, the width of the channels in the die assembly for forming the parallel stripes is substantially greater than the width between the vertically projecting portions for forming the space between the stripes. Similarly, the width of longitudinally space-apart substantially parallel stripes is relatively larger than the space between the stripes, preferably less than 20% of the width. This is believed to promote effective suction to enhance bead formation despite the gaps between beads. Preferably, the suction is greater than 0.1 inches water gauge or iwg (2.5 mm), preferably 3 to 5 iwg (76 mm to 127 mm), more preferably greater than 3.5 iwg (89 mm).

In one embodiment, for example, the striped coating when wet is 10 to 200 microns when first coated and 2 to 20 microns when dried. In the case of a stacked striped layer, the top layer has, for example, a wet coverage of 1 to 6 cc/ft² (11 to 65 cc/m²), preferably greater than 1.3 cc/ft² (14 cc/m²). Similarly, the bottom layer has, in one application, a wet coverage of greater than 38 cc/m² to 76 cc/m².

With respect to two vertically stacked layers, comprising an upper layer and a lower layer, relative to the flexible substrate, the upper layer preferably has a higher viscosity than the lower layer. More preferably, the viscosities of the upper layer and the lower layer are 2 to 150 Centipoises.

In one embodiment, the width of the stripes is 5 mm to 2500 mm (2 inches to 100 inches) and the width of the longitudinal spaces between stripes is 0.5 mm (0.020 inch) to 500 mm (20 inch), preferably at least 1.0 mm ( 1/16 inch).

In such an embodiment, the thickness of each of said shims, corresponding to the thickness of the fluid coating within the die assembly, is 0.076 mm to 0.51 mm (5 to 10 mils). Similarly, the width of the distribution passages for forming the parallel stripes is between 1.5 to 50 mm and the width between the distribution blocks for forming the spaces between the stripes is, respectively, 0.5 mm to 4 mm.

The die assembly is adapted to separately distributes the two coating liquids A and B, respectively, in (a) the lower interfacial fluid-flow space between the lower die element and the center die element to form an extended coating bottom layer in the form of stripes A; and (b) the upper interfacial fluid-flow space between the center die element and the upper die element to form an extended coating secondary (upper) layer in the form of stripes B.

Accordingly, each of two sets of stripes of coating composition can be formed in the die assembly by means of each of said shims which is placed between two die-element interfacial surfaces that are in a substantially parallel, face-to-face relationship, in which one of the element surfaces contains a fluid distribution cavity. A secondary layer of coating composition is superimposed on a bottom layer at the lip of the outlet slot by aligning channels and projecting portions in the upper shim with channels and projecting portions in a bottom shim such that the channels are adapted to form parallel stripes of coating fluid and the spaces between projecting portions are adapted to correspond to the space between the parallel stripes.

In one embodiment of a die assembly that may be employed in the present method, the center die element has, in cross-section, a substantially triangular shape, wherein the upper outlet and the lower outlet share an intermediate edge corresponding to a corner of the triangular shape of the center die, which corner is the corner of the center die element positioned most proximate to the substrate to be coated. The lower die element and bottom-layer shim of the slot-coating device is adapted to distribute the bottom coating composition (coating fluid A) into a plurality of longitudinally parallel discontinuous stripes. A conduit is adapted to introduce coating fluid A into the die assembly and communicates with a cavity adapted to distributes the coating liquid in a direction perpendicular to the edge of the substrate to be coated. The bottom-layer shim contains channels adapted to cause coating fluid A to flow from a cavity to a lower lip of the bottom die element through channels, but vertically projecting portions in the shim are adapted to prevent flow from occurring in the areas covered by the vertically projecting portions of the shim. Whereas the channels are adapted to form spaced-apart stripes of the bottom layer coating composition A, the vertically projecting portions of the bottom layer shim are adapted to form uncoated spaces between the stripes.

Similarly, the upper-layer or second-layer shim is placed between the top face of center die element and the lower face of upper die element, so that a secondary coating composition (coating fluid B) entering the center die element through a conduit communicates with a cavity which is adapted to distribute the coating liquid in a direction perpendicular to the edge of the substrate to be coated. The upper-layer shim contains channels and vertically projecting portions, such that coating fluid B can flow from the cavity to an upper lip of the outlet slot through channels, but wherein flow is prevented from occurring in the areas occupied by the vertically projecting portions of the shim. Accordingly, stripes of upper-layer coating composition B can be formed in the channels but spaces between stripes are formed corresponding to the space occupied by each vertically projecting portions in the upper-layer shim.

The elements of the die assembly are configured such that the stripes of secondary extended layer of coating fluid B are superimposed on top of the stripes of the bottom extended layer of coating fluid A at the upper lip by aligning channels and projecting portions of upper shim with channels and projecting portions of bottom layer shim, whereby stacked stripes can be formed by the die assembly.

The die assembly can be used in an apparatus for stripe coating on a web, wherein the die assembly is further in combination with a means for advancing a web to be coated across and closely adjacent the outlets of the die assembly to receive coating fluid therefrom in the form of stripes corresponding in width and location to the channels in said shims, and further in combination with a suction chamber for imposing a pressure difference across the coating bead for each stacked stripe of material. The means for advancing the web can be a rotatable drum or similar means.

The stripe coating method of the present invention is useful to coat many different types of web materials with many different kinds of liquid coating compositions. For example, the web can be composed of paper, polymer-coated paper such as polyethylene-coated paper, metal foil, or plastic film such as cellulose acetate, polyvinyl acetal film, polyethylene film, polypropylene film, polycarbonate film, polystyrene film or a polyester film.

Web materials that can be successfully stripe-coated with the method or apparatus and described herein can be any suitable width. The stripes can also vary in width as desired and can be spaced a desired distance between stripes. The method can be used to apply stripes of different width and/or different spacing across the width-wise extent of the web, as desired, although uniform stripes and spacing will be among the useful configurations. In sum, the dimensional characteristics of the manufactured product can be varied widely to meet the objectives of a particular end use.

The coating composition can be a solution or dispersion of polymeric material containing dye or pigment, a magnetic dispersion, a phosphor dispersion, a radiation or light sensitive dispersion or emulsion, or an adhesive composition. The production of electronic parts can require a step of applying a coating material is a stripe pattern, particularly when involving spaced electrodes.

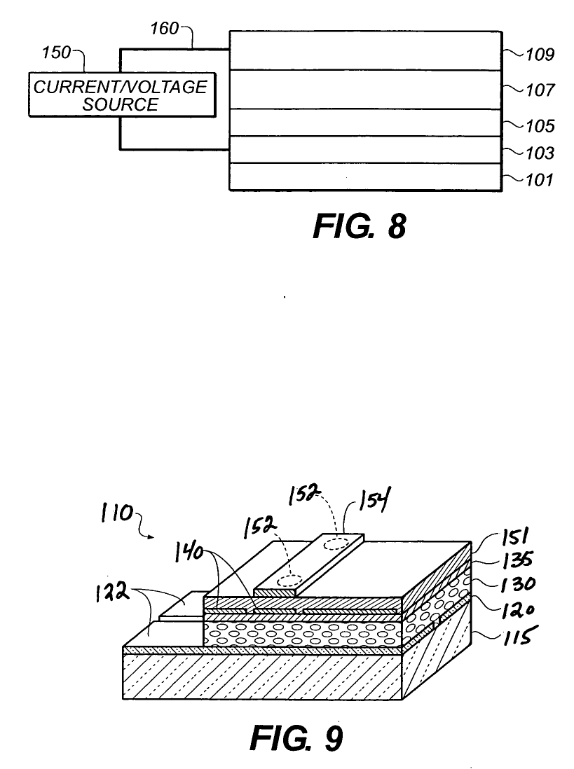

For example, the present method may be used to deposit multi-layer organic materials for use in such electronic devices as organic light emitting diodes (OLEDs), also referred to as organic electroluminescent (EL) devices. One skilled in the art understands that there are numerous possible materials and layer configurations that could be used. Typically, an OLED has two or more organic EL media layers disposed between an anode and cathode. One layer is adjacent to an anode and functions as a hole-injecting and transporting layer (HTL). The second layer is adjacent to the cathode and functions as an electron-injecting and transporting layer (ETL). FIG. 8 shows a typical arrangement of such a structure having a substrate 101, a first electrode (in this example, an anode) 103 provided over the substrate, HTL 105 over the anode 103, ETL 107 over the HTL, and a second electrode (in this example, a cathode) 109 provided over the ETL. A current/voltage source 150 is connected to the anode 103 and cathode 109 by electrical conductors 160 and provides the necessary potential to inject electrons from the cathode into the ETL, and holes from the anode into the HTL. Normally, electrons and holes recombine near the interface of the HTL and the ETL to generate light. Either or both of the HTL and ETL may emit light, depending on the physical properties of the materials and where recombination takes place. Most typically, in this two-layer configuration, recombination occurs primarily in the ETL and the ETL functions as the light-emitting layer. In some systems, a third layer is provided between the HTL and ETL, the properties of which are adjusted in order to provide a suitable recombination zone for light emission. This third layer is often referred to as a light-emitting layer (LEL).

Whether it is the HTL, the ETL, or a specially designed LEL between the HTL and ETL, the light-emitting layer can be comprised of a single compound or material, but more commonly contains a host material doped with a guest emitting material or materials where light emission comes primarily from the emitting materials and can be of any color. This guest emitting material is often referred to as a light emitting dopant. The host materials in the light-emitting layer can be an electron-transporting material, a hole-transporting material, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. The host may be a small, non-polymeric molecular material, or it may be polymeric. The guest emitting material may also be a small molecule, or it can be polymeric. When the host is polymeric, the guest emitting material may be incorporated into the backbone of the polymer, as pendant units, as a copolymer, or as a molecularly dispersed monomer within the polymeric host.

In the multilayer coating method of this invention, the compositions for the coating is provided in liquid or solution form. Polymeric hole-transporting, electron-transporting, and/or light-emitting materials are preferred when fabricating OLED devices using this invention. Suitable examples of polymeric hole transporting materials include poly(N-vinylcarbazole) (PVK), polythiophenes, polypyrrole, polyaniline, polymeric aryl amines, and copolymers including poly(3,4-ethylenedioxythiophene)/poly(4-styrenesulfonate) also called PEDOT/PSS. These can be coating with an organic solvent solution, or in the case of PEDOT/PSS, from an aqueous solution. Suitable examples of polymeric light-emitting and electron transporting materials include polyfluorenes and polyvinylarylenes (e.g., poly(p-phenylenevinylene), PPV). These are also conveniently coated from an organic solvent solution, e.g., toluene. Some non-limiting examples of such polymeric materials useful for OLED devices are found in U.S. Pat. No. 6,391,481, U.S. Pat. No. 6,376,105, “The Handbook of Conducting Polymers, Vol. 1” (1986), Marcel Dekker, Inc., NY, U.S. Pat. No. 5,401,827, U.S. Pat. No. 5,653,914, WO 01/42331, and WO 02/28983, which are incorporated herein by reference. Small molecule materials may be incorporated into the above polymeric solutions to modify their transport or light-emitting properties. Alternatively, active small molecule materials may be provided in a solution along with a soluble, non-electroactive polymeric binder (e.g., polystyrene) that simply aids in film formation.

After coating of the organic EL media fluid, the tacky film can be heated, optionally under reduced pressure, to remove solvent and solidify the film. After deposition of the layers using this method of this invention, other organic layers can be provided in a separate step using a similar deposition method, or by other conventional methods such as vapor deposition.

When EL emission is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are generally immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) that is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862; and 6,140,763.

A metal-doped organic layer can be used as an electron-injecting layer. Such a layer contains an organic electron-transporting material and a low work-function metal (<4.0 eV). For example, Kido et al. reported in “Bright Organic Electroluminescent Devices Having a Metal-Doped Electron-Injecting Layer”, Applied Physics Letters, 73, 2866 (1998) and disclosed in U.S. Pat. No. 6,013,384 that an OLED can be fabricated containing a low work-function metal-doped electron-injecting layer adjacent to a cathode. Suitable metals for the metal-doped organic layer include alkali metals (e.g. lithium, sodium), alkaline earth metals (e.g. barium, magnesium), metals from the lanthanide group (e.g. lanthanum, neodymium, lutetium), or combinations thereof. The concentration of the low work-function metal in the metal-doped organic layer is in the range of from 0.1% to 30% by volume. Preferably, the concentration of the low work-function metal in the metal-doped organic layer is in the range of from 0.2% to 10% by volume. Preferably, the low work-function metal is provided in a mole ratio in a range of 1:1 with the organic electron transporting material.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by means of evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

The present invention can be employed the manufacture of other OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs). In particular, this invention can be used to fabricate multiple OLED devices provided on a flexible substrate. The space between the stripes of organic EL media provides a convenient location for electrical connection pads, for cutting (singulating) the individual devices, and for attachment of other components such as encapsulation layers, printed circuit boards, etc.

The present invention is also useful in the making of a light modulating, electrically responsive sheet comprising a substrate, an electrically conductive layer formed over the substrate, and a light-modulating layer comprising an electro-optical fluid, preferably a chiral nematic material, disposed over the electrically conductive layer formed by the above described methods.

In one preferred embodiment, the present method is used to coat an electro-optical fluid during the manufacture of a plurality of individual displays of the type shown in FIG. 9 in a perspective section view, which display comprises segmented characters and employs a liquid-crystal material.

For example, FIG. 9 shows a display 110 including a flexible substrate 115, which can be a thin transparent polymeric material, such as Kodak Estarg film base formed of polyester plastic that has a thickness of between 120 and 200 micrometers. In an exemplary embodiment, flexible substrate 115 is a 125-micrometer thick sheet of polyester film base. Other polymers, such as transparent polycarbonate, can also be used.

One or more transparent first conductors 120 are formed on flexible substrate 115. Transparent first conductors 120 can be tin-oxide, indium-tin-oxide (ITO), or polythiophene, with ITO being the preferred material. Typically the material of transparent first conductors 120 is sputtered or coated as a layer over flexible substrate 115 having a resistance of less than 1000 ohms per square. Transparent first conductors 120 can be formed in the conductive layer by conventional lithographic or laser etching means. Transparent first conductors 120 can also be formed by printing a transparent organic conductor such as PEDT/PSS, PEDOT/PSS polymer, which materials are sold as Baytron® P by Bayer AG Electronic Chemicals. Portions of transparent first conductors 120 can be uncoated to provide exposed transparent first conductors 122 for this embodiment.

Cholesteric layer 130 overlays transparent first conductors 120. Cholesteric layer 130 contains cholesteric liquid-crystal material, such as those disclosed in U.S. Pat. No. 5,695,682 to Doane et al., the disclosure of which is incorporated by reference. Such materials are made using highly anisotropic nematic liquid crystal mixtures and adding a chiral doping agent to provide helical twist in the planes of the liquid crystal to the point that interference patterns are created that reflect incident light. Application of electrical fields of various intensity and duration can be employed to drive a chiral-nematic (cholesteric) material into a reflective state, to near-transparent or transmissive state, or an intermediate state. These materials have the advantage of having first and second optical states that are both stable in the absence of an electrical field. The materials can maintain a given optical state indefinitely after the field is removed. Cholesteric liquid crystal materials can be formed, for example, using a two-component system such as MDA-00-1444 (undoped nematic) and MDA-00-4042 (nematic with high chiral dopant concentrations) available from E. M. Industries of Hawthorne, N.Y.

In a preferred embodiment, cholesteric layer 130 is a cholesteric material dispersed in photographic gelatin. The liquid crystal material is mixed at 8% cholesteric liquid crystal in a 5% gelatin aqueous solution. The mixture is dispersed to create an emulsion having 8-10 micrometer diameter domains of the liquid crystal in aqueous suspension. The domains can be formed using the limited coalescence technique described in U.S. Pat. No. 6,423,368 by Stephenson et al. The emulsion is coated over transparent first conductors 120 on a polyester flexible substrate 115 and dried to provide an approximately 9-micrometer thick polymer dispersed cholesteric coating. Other organic binders such as polyvinyl alcohol (PVA) or polyethylene oxide (PEO) can be used in place of the gelatin. Such emulsions are machine coatable using coating equipment of the type employed in the manufacture of photographic films. A gel sub-layer (not shown in FIG. 1) can optionally be applied over transparent first conductors 120 prior to applying cholesteric layer 130 as disclosed in U.S. Pat. No. 6,423,368 by Stephenson et al., hereby incorporated by reference in its entirety. The gel sub-layer acts a buffer layer to prevent electrical shortages from occurring during display use.

Dark layer 135 overlays cholesteric layer 130. In a preferred embodiment, dark layer 135 is a light-absorbing layer composed of pigments that are milled below 1 micrometer to form “nano-pigments” in a binder. Such pigments are very effective in absorbing wavelengths of light in very thin (sub-micrometer) layers. Such pigments can be selected to be electrically inert to prevent degradation interference from electrical display fields applied to display 110. Such pigments are disclosed in copending U.S. Ser. No. ______ (Docket 84,140), hereby incorporated by reference.

In FIG. 9, dark layer 135 is coated over cholesteric layer 130 to provide a light-absorbing layer that provides a specific contrast state to reflected light. The coating can be simultaneous with the deposition of cholesteric layer 130 or as a separate step. In this embodiment, the present method provides cholesteric layer 130 and dark layer 135 as two co-deposited layers in a striped pattern as described above. Dark layer 135 is significantly thinner than cholesteric layer 130 and has minimal effect on the electrical field strength required to change the state of the cholesteric liquid-crystal material.

Second conductors 140 overlay dark layer 135. Second conductors 140 have sufficient conductivity to induce an electric field across cholesteric layer 130 strong enough to change the optical state of the polymeric material. Second conductors 140 are preferably formed by vacuum deposition of conductive material such as aluminum, chrome, silver or nickel. The layer of conductive material can be patterned using well-known techniques such as photolithography, laser etching or by application through a mask. In another embodiment, second conductors 140 can be formed by screen printing a reflective and conductive formulation such as UVAG® 0010 from Allied Photochemical of Kimball, Mich. Such screen printable conductive materials comprise finely divided silver in ultraviolet-curable resin. After printing, the material is exposed to ultraviolet radiation greater than 0.40 Joules/cm², the resin will polymerize in 2 seconds to form a durable surface. Screen printing is preferred to minimize the cost of manufacturing the display. Alternatively, second conductors 140 can be formed by screen printing a thermally cured silver-bearing resin. An example of such a material is Acheson Electrodag® 461 SS, a heat cured silver ink. In the case that the dark layer 135 is black, any type of conductor can be used including black carbon in a binder.

Referring still to FIG. 9, a dielectric layer 150 can be provided over second conductors 140. Dielectric layer 151 is provided with a plurality of “through via holes” 152 that permit interconnection between each second conductor 140 and conductive traces 154. Dielectric layer 151 is formed, for example, by coating, or printing, a vinyl polymer dissolved in a solvent. Third conductors or traces 154 (sometimes referred to as electrical tracers) can be formed by screen printing the same screen-printable, electrically conductive material used to form second conductors 140. The third conductors or traces 154 enable the connection of common segments in different characters, thereby creating functional rows of electrically addressable areas in the polymer-dispersed cholesteric liquid-crystal layer. The third conductors or traces and exposed first conductors 122 form a set of backside display contacts that are used to electrically address the display.

The display element shown in FIG. 1 represents one embodiment of a segmented display. In contrast to the structure of the segmented display of FIG. 1, a pixilated display typically does not require the dielectric layer of the third conductors. Moreover, the patterns for the first and second conductors for a segmented display differ from a pixilated display. The pattern for the second conductors in a pixilated display typically comprises numerous parallel bars perpendicular to numerous parallel bars forming the first conductors, whereas the second conductors in the segmented display typically vary in shape and size, for example, as do the segments of alphanumeric characters, and the first conductors are each in the form of larger areas (for example, sequential rectangular areas) that are each under a plurality of second conductors.

The use of a flexible support for flexible substrate 115; thin transparent first conductors 120; machine-coated cholesteric liquid-crystal layer 130; and printed second conductors 140 permits the fabrication of a low-cost flexible display. Small displays can be used as electronically rewritable tags or labels for inexpensive, rewrite applications.

In a preferred embodiment of a display, the cholesteric material (also referred to as chiral-nematic) can exhibit two stable optical states. For example, it is known that applying a higher voltage field and quickly switching to zero potential causes such liquid crystal molecules to become planar liquid crystals. On the other hand,, application of a lower voltage field causes molecules of the cholesteric liquid crystal to break into transparent tilted cells that are known as focal-conic liquid crystals. Varying electrical field pulses can progressively change the molecular orientation from planar state to a fully evolved and transparent focal conic state.

A thin layer of light-absorbing submicron carbon or a nanopigment in a gel binder can be disposed between second conductors and polymer-dispersed cholesteric layer as disclosed in copending U.S. Ser. No. 10/036,149 filed Dec. 26, 2001 by Stephenson et al., hereby incorporated by reference. Focal-conic liquid crystals are transparent, passing incident light, which is absorbed by second conductors to provide a black image. Progressive evolution from planar to focal-conic state causes a viewer to see an initial bright, reflected light which transitions to black as the cholesteric material changes from planar state to a fully evolved focal-conic state. The transition to the light-transmitting state is progressive, and varying the low-voltage time permits variable levels of reflection. These variable levels can be mapped out to corresponding gray levels, and when the field is removed, polymer dispersed cholesteric layer maintains a given optical state indefinitely. The states are more fully discussed in U.S. Pat. 5,437,811.

A process for fabricating display 110, in this case pixilated, in accordance with the present method will now be described.

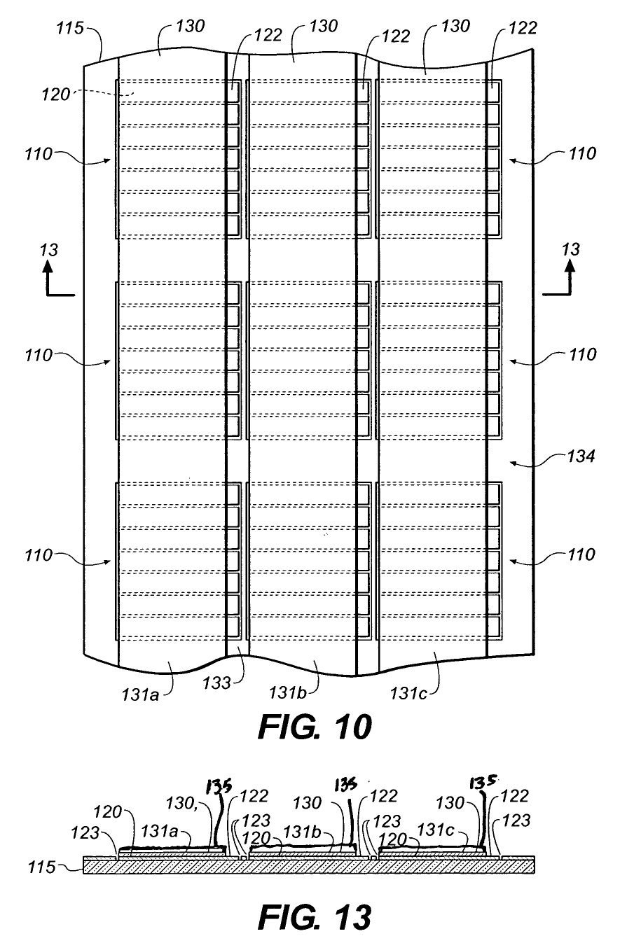

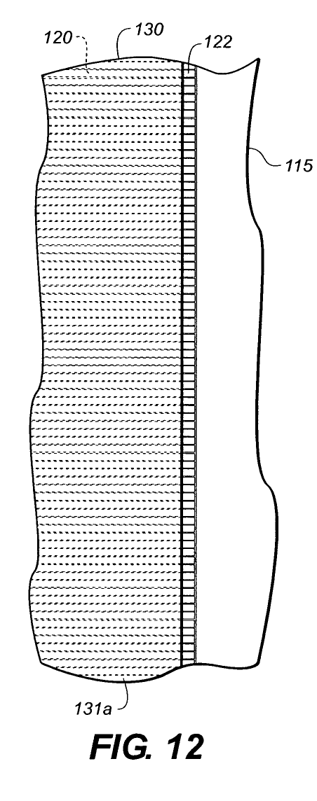

FIG. 10 is top view of a continuous common flexible substrate 115 having a plurality of partially completed display elements 110 (manufacturing intermediates for display elements 110) coated in accordance with the present invention. The outside periphery of the sets of first conductors 120 of each display element is shown outlined, in part by a dotted line. Within the dotted periphery, there typically are formed a plurality of first conductors in the form of narrow bars. (Although only seven bars are diagrammatically shown in FIG. 10, they are intended to represent numerous bars as more accurately depicted in FIG. 12, in magnified view compared to FIG. 10.) The sets of first conductors 120 on common flexible substrate 115 are formed for each individual display element 110 on the common flexible substrate 115 and arranged in series along each coated stripe layer of cholesteric material. In accordance with one embodiment of the invention, stacked striped layers, one of which is a polymer-dispersed cholesteric material, in striped layers 131a, 131b, 131c is selectively deposited over the sets of first conductors 120 in a manner that leaves portions of each of the first conductors 120 in the set of first conductors exposed for each display element 110. The method permits roll-to-roll manufacture of display elements on a common flexible substrate 115 with minimal waste of deposited polymer-dispersed cholesteric layer 130. The exposed transparent first conductors 122 can be seen in the uncoated longitudinal space 133. This uncoated space allows (as shown later), in the completed display, electrical connection with contacts to a driver for the display that may be coupled or uncoupled to the display. The width of the exposed first conductors 122 in the space 133 can vary, and may even essentially fill the entire space. It will be noted that a leader space 134 exists between display elements, the length of which can also vary, preferably shortened to reduce waste during later singulation of the display elements.

The display elements 110 can be arrayed as shown in FIG. 10 or there can be any number of rows (and corresponding stripes and longitudinal spaces) on a flexible substrate in the form of a moving web. Alternatively, a non-continuous common flexible substrate 115 in the form of a separate sheet of any length short of a web and having an array, or plurality, of display elements 110 can be transported, for example by means of a conveyer belt.

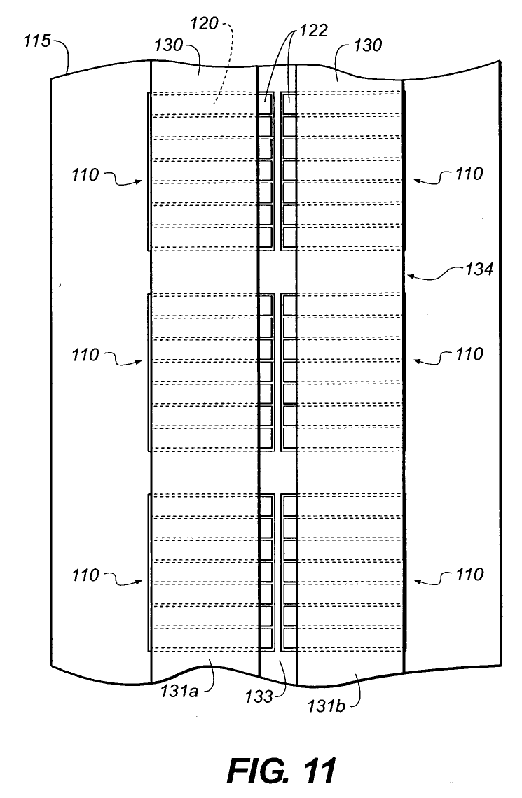

FIG. 11 is a top view of an alternate embodiment according to the present invention showing a continuous common flexible substrate 115 having a plurality of partially completed display elements 110 (actually manufacturing intermediates for display products), in which the display elements are separated in the direction of the arrow by leader spaces 134, in accordance with the present invention. The periphery of the sets of first conductors 120 of each display element is shown in part outlined by a dotted line. The sets of first conductors 120 are formed for each individual display element 110 on the common flexible substrate 115 and arranged in series along each of the coated striped, at least one of which layers in stripes 131a, 131b is a cholesteric material. In accordance with this embodiment of the invention, polymer-dispersed cholesteric material is the bottom layer of the striped coatings 131a, 131b, the upper layer of which is a striped dark layer, and is selectively deposited over the sets of first conductors 120 in a manner that leaves portions 122 of each of the first conductors 120 in the set of first conductors exposed for each display element 110 and wherein the exposed longitudinal area, between the adjacent rows of display elements covered by adjacent stripes of cholesteric material, provide unexposed transparent first conductors that are adjacent and parallel. In this embodiment, a single longitudinal space 133 contains the exposed portions 122 of the first conductors for both series of elements in, respectively, stripes 131a and 131b. The width of the two sets of exposed portions of first conductors 122 in the space 133 can vary, and may even essentially fill the entire space, although a separation between adjacent exposed conductors is shown in FIG. 11 for clarity. It will be noted that a leader space 134 exists between display elements, the length of which can also vary, preferably shortened to reduce waste during later singulation of the display elements.

FIG. 12, as mentioned above, is a more detailed, magnified top view of an individual display element shown diagrammatically in FIG. 11, having patterned transparent first conductors coated with cholesteric material. FIG. 12 shows the numerous first conductors that are typically used in pixilated display, which was diagrammatically represented by a lesser number of first conductors in FIG. 11 for purposes of simplification. First conductors 120 can be formed by laser etching electrically separated areas on an ITO coating. (The space between first conductors can be very narrow (on a micron scale) and the width of the etching is, therefore, not shown to scale in the figures.) First conductors can also be printed organic conductors such a PEDOT using conventional coating or printing techniques.

In this particular embodiment, at least one of the striped layers is a cholesteric material in the form of an emulsion is deposited as a layer of wet polymer-dispersed cholesteric liquid crystal over first conductors 120, leaving uncovered portions 122. The deposited emulsion thickness is set by the concentration of emulsion material, the flow rate of the material and the machine coating speed. In one embodiment, the parameters are selected to provide a 61-micron thick wet coating of emulsion. The viscosity of the emulsion can also be controlled by the concentration of liquid carrier, in this case water, in the emulsion and by controlling the temperature of coating.

FIG. 13 is a side view of the display element of FIG. 12, taken through line 13-13 of FIG. 12, including a portion of an adjacent striped area on the common flexible web 115, in which dried stripes 131a, 131b, are coated over first conductors 120 leaving uncovered areas of first conductors 122. Etched space 123 is present between parallel sets of first conductors. Material has been deposited only in areas needed for image display. The striped layer comprises as an upper layer a dark layer.

Other means for selectively coating or depositing additional layers (including, for example, gel layers, additional cholesteric layers, etc.) can be used downstream or upstream from the coating station for the cholesteric layer. For example, other layers can be deposited employing a mask, gravure printing, screen printing, transfer printing, spray printing, inkjet printing, or other conventional printing means known to the skilled artisan. In yet other embodiments, as described layer, stacked layers in a striped coating can be applied simultaneously, for example, a gel layer and a cholesteric layer, or two different cholesteric layers, or a gel layer and a cholesteric layer and a nanopigment layer can be applied simultaneously in a stripe coating.

Subsequent to the stripe coating of stacked layers of material according to the present invention, second conductors can be applied to the display elements, for example, on the same moving web shown in FIG. 11 after selective coating of the polymer dispersed cholesteric layer. Alternatively, second conductors can be applied to display elements after the array of display elements have been divided or cut into discrete sheets containing a selected subset of display elements or singulated into an individual display element.

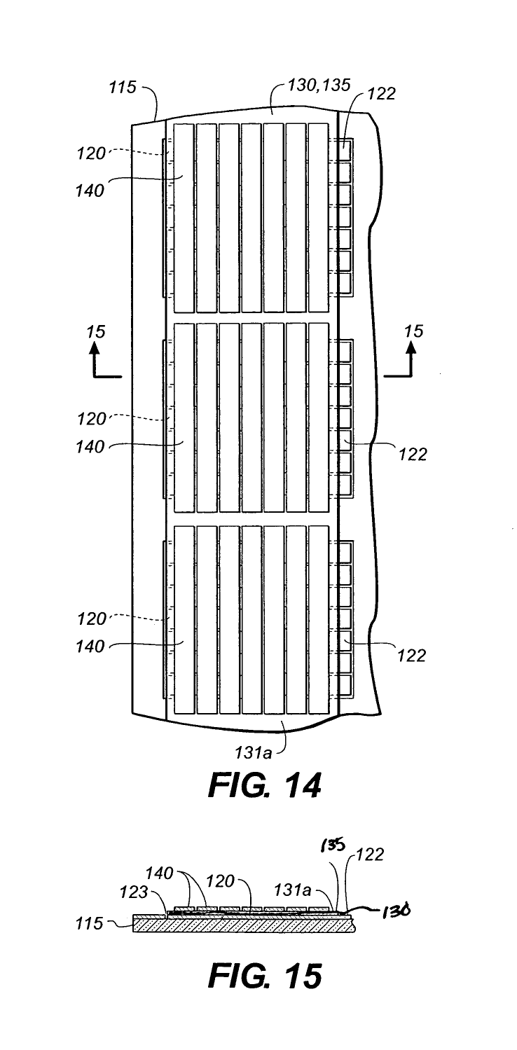

FIG. 14 is a top view of one embodiment of the display elements of FIG. 13 with the later addition of printed second conductors 140. Second conductors 140 can be printed over dried material in stripe 131a. Under the stripe 131a, an ITO coating is shown covering flexible substrate 115. First conductors 120, including exposed portions 122, can be etched into the ITO coating. Optionally, printing portions of the same material used to create second conductors 140 over the exposed transparent first conductors 120 can provide protective coverings or pads over exposed first conductor 122.

FIG. 15 is a bounded side view of a completed individual display element (singulated from the continuous substrate) with printed second conductors 140 having electrically addressable pixels, which side view is taken through section 15-15 of FIG. 14, showing cholesteric layer 130, dark layer 135, etched line 123 in a first conductive layer forming first conductor 120, and exposed portion 122 on flexible substrate 115.

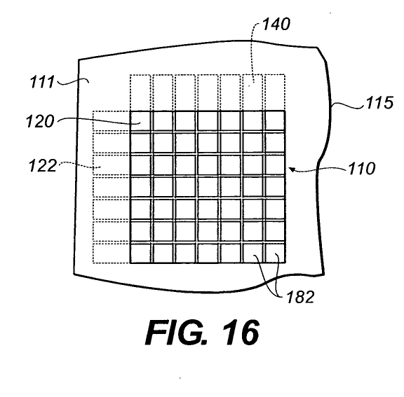

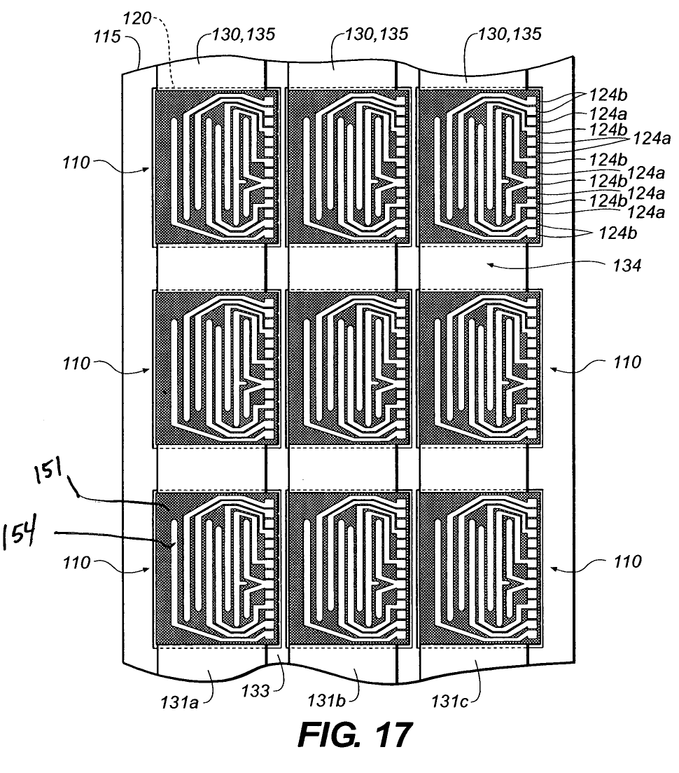

FIG. 16 is a schematic drawing of an extended front view (viewed from the support or substrate side of flexible substrate 115) of the single display element 110 of FIG. 15 comprising a front display area 111. The display element 110 has been singulated from the display elements 110 shown in FIG. 16. Display element 110 has pixels 182 shown in bolder line. Referring to FIG. 14 and 16 together, contacts can be applied, respectively, to each first conductor 120 and each second conductor 140. Appropriate electrical signals applied to first conductors 120 and second conductors 140 permit writing of image data onto display element 110.

As mentioned earlier, the second coated layer (stacked under or over the striped cholesteric layer) can comprise a dark layer (i.e., a pigmented or dyed layer) coated between the cholesteric layer and second conductors, to improve the contrast of display element. Alternatively, a second or third striped coated layer can be another emulsion containing cholesteric liquid crystal different in properties than the first cholesteric layer. For example, the second striped coated layer can comprise a differently colored cholesteric liquid-crystal material. The differently colored cholesteric liquid-crystal material can be a different wavelength of light reflected by the planar state, in order to provide multicolor displays.

The displays described above can be combined with conventional components to obtain an integral self-contained system. For example, matrix driving of such cholesteric displays are well known in the art, as for example, described in U.S. Ser. No. 10/085,851 filed Feb. 28, 2002, hereby incorporated by reference in its entirety.

The method of the present invention is also applicable to segmented, as compared to the pixilated displays.

In the case of a segmented display, the set of first conductors for each individual display is typically in the form of individual segments, each segment corresponding, for example, to an alphanumeric character or other indicia or picture element as desired. A method of making segmented displays are disclosed in copending U.S. Ser. No. ______ (docket 88360), hereby incorporated by reference in its entirety.

In this embodiment, a dielectric layer is optionally applied over the second conductors, which may optionally be applied in a rectangular shape, for each individual display element, within the portion of the coated stripe associated with the display element. The dielectric layer covers second conductors, but the presence of through-vias permits access to second conductors.

The through-vias permit connection to segmented second conductors to permit writing of cholesteric liquid crystal material to either the focal-conic or planar state during display use. Design of multiple printed layers to create a matrix driven seven-segment display having electrically writable inter-segment material are incorporated in co-pending U.S. application Ser. No. 10/426,539 by the same inventors, which application is hereby incorporated by reference in its entirety.

Instead of coating a dielectric layer, air may be used as a dielectric material in combination with suitable spacing achieved by contacts.

FIG. 17 is a plan rear view of segmented display elements on a sheet (still a manufacturing intermediate for a display) that has been made using the present invention, showing flexible substrate 115, individual display elements 110, coated stripes 131a, 131b, 131c and inter-stripe gaps or spaces 133, in which are conductive contacts 124a, 124b. Conductive contacts 124a provide electrical connection with exposed first conductors 122. Conductive contacts 124b provide connection to second conductors via the third conductors 154. The stripes include (below the dielectric layer and hence not visible in FIG. 17) a stacked cholesteric layer 130 and dark layer 135, for example comprising a nanopigment, over which dark layer is coated the dielectric layer.

Conductive traces 154 are printed to connect common second conductors using through vias 152 in dielectric layer 150. The conductive traces or third conductors form a predesigned path leading to conductive contact 124a for a display driver in the longitudinal spaces 133. Conductive contacts 124a, 124b can be connected, respectively, to second conductors via the conductive traces 154 and to the first conductors via through holes 125. In the later case, the conductive contacts may be viewed as protective pads formed on the exposed portions of transparent conductors 122, especially in the case where the dielectric is patterned, instead of using via holes 125, to expose the first conductors in the inter-stripe longitudinal space. The transparent conductors 120 are typically made of ITO which can be subject to undesirable scratching. In the embodiment shown in FIG. 17, the conductive contacts 124a, 124b for connection to a display driver, are advantaeously all in the longitudinal space along the side of the display characters, thereby obviating the need for removing a portion of the imaging layer or other layers that have been coated over the first conductors in order to allow contact with the first conductors.

A completed display assembly in accordance with the present invention can be connected to an electric driver via driver contacts (for both the first and second conductors) to conductive conducts 124a, 124b in FIG. 17 which are connected to conductive traces 154 in FIG. 17. Electrical signals can be applied to driver to write images onto the display. Segments of the display are typically written into the darker, focal-conic state to present image data. Writing data segments back into the electrically written planar state merges the previously written area into an optically continuous background.

In use, a display can comprise a circuit board attached to the assembly made. Contacts on the circuit board can provide electrical connection to each second conductor and first conductor via contacts in the uncoated space adjacent the striped material, the overall assembly of which will be understood by the skilled artisan.

### EXAMPLE 1

A coating pack of a two-layer gelatin system was applied to a substrate having a 250-Angstrom thick conductive layer of an. Indium Tin Oxide (300 ohms per square) on a 120-micron polyethylene terephthalate substrate, using a slot hopper. The Indium Tin Oxide coated on the polyethylene terephthalate was prepared by Bekaert Specialty Films, LLC, San Diego, Calif. The bottom layer coating composition was a 5 wt % gelatin material containing 13.3 wt % of MERCK BL118 droplets of cholesteric liquid crystal oil, available from E. M. Industries of Hawthorne, N.Y. U.S.A. The droplets, created by a limited coalescence per Stephenson U.S. Pat. No. 6,556,262 B1, had a volume mean diameter of 10 microns. The coating solution was heated to 45° C., which reduced the viscosity of the emulsion to approximately 8 centipoises. A three percent by weight gelatin cross-linker bisvinylsulfonylmethane was dueled with the bottom layer coating solution immediately prior to coating. The dueled solution was continuously coated on the coated substrate at 61.5 ml/m² on a photographic coating machine.

The top layer coating solution was prepared using 4 wt % gelatin and a mixture of pigments formulated to provide a neutral black density. The second coating solution was heated to 45° C., and the viscosity of the solution was approximately 100 centipoises. The solution was continuously coated on the coated substrate at 10.76 ml/m² on a photographic coating machine.

A gelatin sub layer was prepared as follows. The coating for the gelatin sub layer contains 2% gelatin by weight with a surfactant (ARCH CHEMICALS, INC., 10G diluted to 10% active ingredient) added to it for coating purposes.

In the case of the gelatin sub layer, the coating composition was heated to 40° C., which reduced the viscosity of the emulsion to 2 Centipoises. This layer was coated as three parallel, spaced-apart stripes at a coating station using a single X-hopper, which was selectively deposited, by the use of shims internal to the single X-hoppers.

At a coating station, the bottom-layer coating solution and the top layer coating solution were coated simultaneously in three parallel spaced-apart stripes over the previously coated gel layer, and in register therewith, using a dual X-hopper separated by a wedge. The two coating solutions were selectively deposited by the use of shims internal to the X-hoppers. A slot coating apparatus was used to coat the three parallel, spaced-apart, vertically-stacked stripes on a sub-layer stripes, thereby forming a total composite stacked stripe, on the support, composed of the gelatin sub-layer, the bottom layer coating composition and the upper layer coating composition

The dimensions of the coating die assembly was as follows:

| | | |
|---|---|---|
| Distance from hopper lip to support | 0.2032 | mm |
| Diameter of hopper cavities | 12.7 | mm |
| Length of flow channels | 25.6 | mm |
| Thickness of shims | 0.254 | mm |
| Width of flow channels | 18.26 | mm |
| Width of shim projection separating portions | 1.60, 2.38, 3.175 | mm |

The two-layer striped coating composition was applied to the gel-coated substrate at a coating speed of 102 cm/s. The machine speed was set so that the temperature of the stacked coating was reduced to 10° C. in a first chill section of the machine. The viscosity of the stacked coating increased so that the coating viscosity changed from a liquid state to a very high-viscosity gel state. The emulsion chill-set hard enough to allow both warm impingement air and the ability to be passed over roller sets in drying areas of the photographic coating equipment to remove the bulk of the water content of the emulsion.

The wet coating thickness of the bottom layer coating composition was 61.5 microns, and the wet coating thickness of the top layer coating composition was 10.8 microns. A stable coating was achieved when a pressure differential of 500 Pascal was applied across the coating bead by means of a suction chamber and vacuum pump. The width of the coated two-layer stripes varied between 18.29 and 18.54 mm which agrees very closely, to within 0.3 mm, of the aim stripe width of 18.26 mm defined by the width of the flow channels of the shims. The -excess laydown in the edge regions of the coated stripes was measured by densitometry and found to be within acceptable limits.

The various widths of shim projection portions (1.60, 2.38, 3.175 mm) produced gaps between the stripes that were within 0.25 mm of the width of the stripe shim projection portions.

The resulting dried coating stripe thickness (of both coated layers) was about 9 μm thick. The dried emulsion had flattened domains of cholesteric liquid crystal dispersed in a gelatin polymeric matrix.

The invention has been described in detail with particular reference to certain preferred embodiments thereof, but it will be understood that variations and modifications can be effected within the spirit and scope of the invention.

### PARTS LIST

10 die-coating apparatus

11 backing roller

12 die assembly

13 lower die element

14a bottom-layer shim

14b second-layer shim

14c third-layer shim

15 flexible web

16 center die element

17 upper die element

18a feed conduit

18b feed conduit

18c feed conduit

19a cavity

19b cavity

19c cavity

20a coated striped layer

20b coated striped layer

21 coating bead

23 longitudinal spaces between stripes

30 suction chamber

33a distribution passage

33b distribution passage

34a distribution block

34b distribution block

35a lower lip

35b middle lip

35c upper lip

36 through-openings

38 first center die element

40 second center die element

Parts List—Continued

101 OLED substrate

103 anode

105 hole-injecting and transporting layer

107 electron-injecting and transporting layer

109 cathode

110 display

111 front display area

115 flexible substrate

120 transparent first conductors

122 exposed transparent first conductors

123 etched lines 123 is conductive layer

124a bottom conductive contact

124b top conductive contact

130 cholesteric layer

131a coated stripe layer

131b coated stripe layer

131c coated stripe layer

133 inter-stripe longitudinal space

134 inter-display leader

135 dark layer

140 second conductors

150 current/voltage source

160 electrical conductors

151 dielectric layer

152 through vias to second conductors

154 conductive third conductors or traces

184 pixels

1. A method of coating comprising forming an extended coating layer comprising a plurality of spaced-apart parallel stripes on a moving web, each stripe composed of at least two different coatable materials in an arrangement of vertically stacked stripes on top of one another comprising in a repeated pattern, at least two stripes alternating with at least one uncoated lateral longitudinal space, in the extended coating layer, and wherein the width of the lateral longitudinal space between the stripes is relatively narrow compared to the width of the stripes and wherein the stripes are formed under suction.

2. The method of claim 1 wherein the plurality of spaced-apart parallel stripes alternate with uncoated lateral longitudinal spaces in the extended coating layer, as follows:
$$\frac{B}{A} ** \frac{B}{A} ** \frac{B}{A}$$
wherein the symbol “**” implies that there is no coating between two adjacent parallel stripes; and wherein A and B represent at least two different coating liquids, and in which B has a distinct interface with A in each stripe.

3. The method of claim 1 wherein the plurality of spaced-apart parallel stripes alternate with uncoated lateral longitudinal spaces in the extended coating layer, as follows:
$$\begin{matrix}\underline{C} \underline{C} \underline{C} \\ \underline{B} ** \underline{B} ** \underline{B} \\ A A A\end{matrix}$$
wherein the symbol “**” implies that there is no coating between two adjacent parallel stripes; and wherein A, B, and C represent at least two different coating liquids, and in which B has an distinct interface with A and C.

4. The method of claim 3 wherein A, B, and C correspond to three different materials.

5. The method of claim 3 wherein A and C are the same material.

6. The method of claim 1 wherein the stripes are substantially level at the top.

7. The method of claim 1 wherein the spaced-apart parallel stripes of the coatable material are formed on a moveable substrate having on its surface a first field-carrying layer forming first conductors.

8. The method of claim 1 wherein at least one of the coatable materials comprises an electro-optical fluid having a plurality of optical states responsive to electric fields.

9. The method of claim 8 wherein the electro-optical fluid is a liquid crystal or an electrophoretic material.

10. The method of claim 1 wherein at least one of the coatable materials comprises a composition for a sensor that, upon detecting a stimuli, allows an electrical signal to be detected.

11. The method of claim 1 wherein at least one of the coatable materials is an organic material for use in an organic light emitting diode.

12. The method of claim 11 wherein at least one of the coatable materials is an organic light-emitting layer disposed between an anode and cathode.

13. The method of claim 11 wherein at least one of the coatable materials is a hole-injecting and transporting layer, an electron-injecting and transporting layer and/or a light-emitting layer.

14. The method of claim 1 wherein at least one of the materials comprises an electro-optical material and the other comprises a darkly pigmented material.

15. The method of claim 1 further comprising coating or printing a field-carrying layer comprising second conductors over the extended coated layer.

16. The method of claim 1 wherein exposed portions of electrodes are situated in longitudinal spaces between said parallel stripes.

17. The method of claim 1 wherein the width of the stripes is 5 mm to 2500 mm (2 inches to 100 inches) and the width of the longitudinal spaces between stripes is 0.5 mm (0.020 inch) to 500 mm (20 inch).

18. The method of claim 1 wherein the suction is greater than 0.1 inches water gauge (2.5 mm).

19. The method of claim 3 wherein the vertically stacked layers comprises an upper layer and a lower layer, relative to the flexible substrate, and wherein the upper layer has a higher viscosity than the lower layer.

20. The method of claim 19 wherein the viscosity of the upper and lower layers are 20 to 150 Centipoises.

21. The method of claim 3 wherein the top layer has a wet coverage of 1 to 6 cc/ft² (11 to 65 cc/m²).

22. The method of claim 3 wherein the bottom layer has a wet coverage of greater than 38 cc/m² to 76 cc/m².

23. A method of coating comprising forming on a flexible substrate, on which is coated a plurality of first electrodes, an extended coating layer comprising a plurality of spaced-apart parallel stripes, each stripe composed of at least two different materials in an arrangement of vertically stacked stripes on top of one another, at least one of such stripe layers comprises an organic EL media fluid, wherein the vertically stacked stripes comprising in a repeated pattern, stripes alternating with uncoated lateral longitudinal spaces in the extended coating layer, as follows:
$$\frac{B}{A} ** \frac{B}{A} ** \frac{B}{A}$$
wherein the symbol “**” implies that there is no coating between two adjacent parallel stripes; and wherein A and B represent at least two different coating liquids, and in which B has an distinct interface with A in each stripe; wherein the width of the lateral longitudinal space between the stripes is relatively narrow compared to the width of the stripes and wherein the stripes are formed under suction and wherein exposed portions of said first electrodes are situated in longitudinal spaces between said parallel stripes; and thereafter applying second conductors over the extended coated layer, thereby forming a sheet product comprising sets of spaced apart electrodes.

24. The method of claim 23 wherein, prior to applying the second conductors, the flexible substrate is singulated along its length into a series of panels each having a plurality of parallel stripes and, separated by leaders, separate elements each having a set of first conductors and second conductors between which is stripe-coated material.

25. The method of claim 23 wherein the sets of second conductors are applied sequentially in separate panels, over four parallel stripeeach parallel stripe.

26. The method of claim 25 wherein further comprising singulation of the sheet product into separate display elements each having a set of first conductors and second conductors between which is stripe-coated material.

27. A method of making an OLED sheet material comprising in order:
(a) forming an extended coating layer comprising a plurality of spaced-apart parallel stripes, each stripe composed of at least two different materials in an arrangement of vertically stacked stripes on top of one another comprising in a repeated pattern, stripes alternating with uncoated lateral longitudinal spaces in the extended coating layer, as follows:
$$\frac{B}{A} ** \frac{B}{A} ** \frac{B}{A}$$
wherein the symbol “**” implies that there is no coating between two adjacent parallel stripes; and wherein A and B represent at least two different coating liquids, and in which B has an distinct interface with A in each stripe; wherein the width of the lateral longitudinal space between the stripes is relatively narrow compared to the width of the stripes and wherein the stripes are formed under suction and wherein exposed portions of said first electrodes are situated in longitudinal spaces between said parallel stripes;
(b) changing the state of the organic EL fluid from a liquid to a solid state; and
(c) applying a second field-carrying layer comprising second conductors over the extended coated layer.
